(19) United States
(12) Patent Application Publication
(10) Pub. No.: US 2026/0202448 A1
(43) Pub. Date: Jul. 16, 2026

(54) DIFFERENTIAL SAMPLING CIRCUIT

(71) Applicant: REALTEK SEMICONDUCTOR CORP., HsinChu (TW)

(72) Inventor: Shih-Hsiung Huang, HsinChu (TW)

(73) Assignee: REALTEK SEMICONDUCTOR CORP., HsinChu (TW)

(21) Appl. No.: 19/440,126

(22) Filed: Jan. 5, 2026

Related U.S. Application Data
(60) Provisional application No. 63/743,749, filed on Jan. 10, 2025.

(30) Foreign Application Priority Data
Jun. 20, 2025 (TW) 114123405

(51) Int. Cl. G01R 19/25; G01R 19/00; H03F 1/02

(52) U.S. Cl. CPC G01R 19/2509; G01R 19/0084; H03F 1/0211

(57) ABSTRACT

A differential sampling circuit is configured to sample a differential circuit. The differential circuit includes a first output and a second output, and the differential sampling circuit includes an amplifier and a switch circuit. The switch circuit includes a capacitor, a pair of sampling switches, and a pair of output switches. One end of the capacitor is coupled to the first output of the differential circuit through one of the pair of sampling switches, and is coupled to a reference terminal through the one of the pair of output switches. The other end of the capacitor is coupled to the second output of the differential circuit through the other of the pair of sampling switches, and is coupled to an input terminal of the amplifier through the other of the pair of output switches.

### CROSS-REFERENCE TO RELATED APPLICATION

This non-provisional application claims the benefit of US provisional application serial No. 63/743,749, filed on January 10, 2025 and claims the priority of Patent Application No. 114123405, filed in Taiwan, R.O.C. on June, 20, 2025. The entire of the above-mentioned patent applications is hereby incorporated by references herein and made a part of the specification.

### BACKGROUND

### Technical Field

The present disclosure relates to a sampling circuit, and in particular, to a sampling circuit configured to sample a differential circuit.

### Related Art

The applicant proposed a switched-capacitor (SC) circuit in the previous research (patent No.: TWI456894B). The SC circuit includes a plurality of first capacitors, a plurality of second capacitors, and a switch circuit. The switch circuit includes a plurality of switches, and each switch is composed of elements based on a bootstrapped sampling switch circuit (Bootstrapped switch). When the SC circuit is applied to differential signal sampling, a plurality of first capacitors correspond to a signal input terminal thereof and a plurality of second capacitors correspond to another signal input terminal. In this way, the first capacitors and the second capacitors can respectively sample a differential pair of a differential signal amplifier.

However, regardless of the plurality of first capacitors or the plurality of second capacitors of the SC circuit, each capacitor can accumulate only single-ended signal potential difference (that is, a potential difference between an input signal and a reference potential) during differential sampling. Therefore, to achieve sufficient amplification, the SC circuit uses a plurality of first capacitors or second capacitors to accumulate charges to make up for a low feedback factor of the circuit. However, this also results in relatively high production costs and circuit complexity of the SC circuit.

### SUMMARY

In view of this, the applicant proposes a differential sampling circuit configured to sample a differential circuit. The differential circuit includes a first output and a second output, and the differential sampling circuit includes an amplifier and a first switch circuit. The first switch circuit includes a first capacitor, a pair of first sampling switches, and a pair of first output switches. One end of the first capacitor is coupled to the first output of the differential circuit through one of the pair of first sampling switches and is coupled to a first reference terminal through the one of the pair of first output switches. The other end of the first capacitor is coupled to the second output of the differential circuit through the other of the pair of first sampling switches and is coupled to a first input terminal of the amplifier through the other of the pair of first output switches.

### BRIEF DESCRIPTION OF THE DRAWINGS

FIG. 1A is a circuit diagram of a differential sampling circuit in a first phase according to a first embodiment.

FIG. 1B is a circuit diagram of the differential sampling circuit in a second phase according to the first embodiment.

FIG. 2A is a circuit diagram of a differential sampling circuit in a first phase according to a second embodiment.

FIG. 2B is a circuit diagram of the differential sampling circuit in a second phase according to the second embodiment.

FIG. 3A is a circuit diagram of a differential sampling circuit in a first phase according to a third embodiment.

FIG. 3B is a circuit diagram of the differential sampling circuit in a second phase according to the third embodiment.

FIG. 4A is a circuit diagram of a differential sampling circuit in a first phase according to a fourth embodiment.

FIG. 4B is a circuit diagram of the differential sampling circuit in a second phase according to the fourth embodiment.

### DETAILED DESCRIPTION

To make objectives, means, and effects of the technical means disclosed in different embodiments of the present disclosure easier to understand, specific embodiments of the proposed technical means are described in detail below with reference to drawings. The following descriptions of the technical means in the embodiments of the present disclosure are for illustration only, and do not represent all embodiments of the present disclosure or limit the present disclosure to specific embodiments. Unless otherwise defined, all technical terms and jargons used in the present disclosure have the same meanings as commonly understood by a person of ordinary skill in the art to which the present disclosure belongs. The terms used in the present disclosure are merely intended to describe objectives of the specific implementations, and are not intended to limit the present disclosure.

Terms "left", "right", "up", "down", and similar expressions used in the present disclosure are merely used to express relative positional relationship based on the drawings, and do not indicate that elements using the terms can be implemented only in the indicated manner. When an absolute position of a described object changes, the description of the relative position may change accordingly. A term "a/an" or "one" used in the present disclosure is used to describe an element and a component of the present invention. The term is merely used for the convenience of description and providing a basic concept of the present invention. The description is to be understood to include one or at least one, and unless explicitly indicated otherwise, include plural when indicating singular. A term "include" is an open term and therefore should be explained as "include but not limited to".

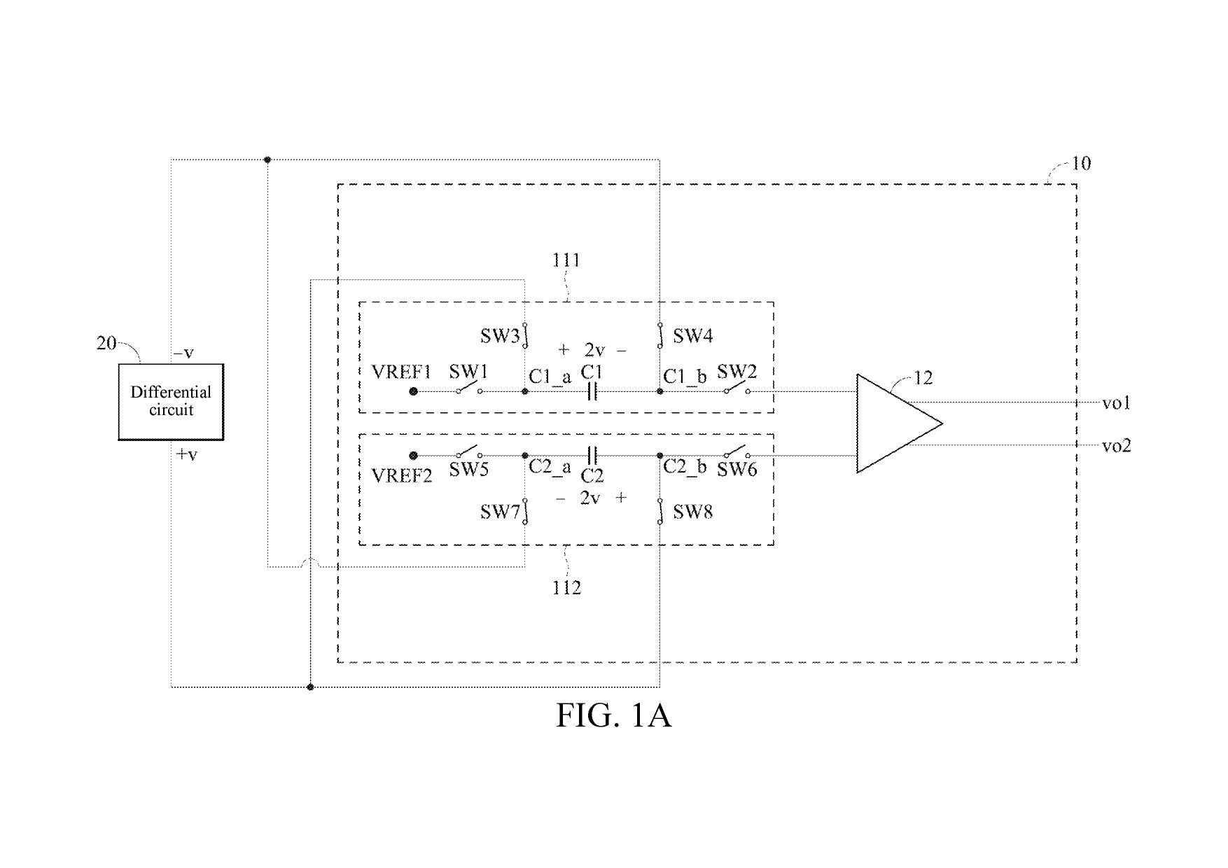

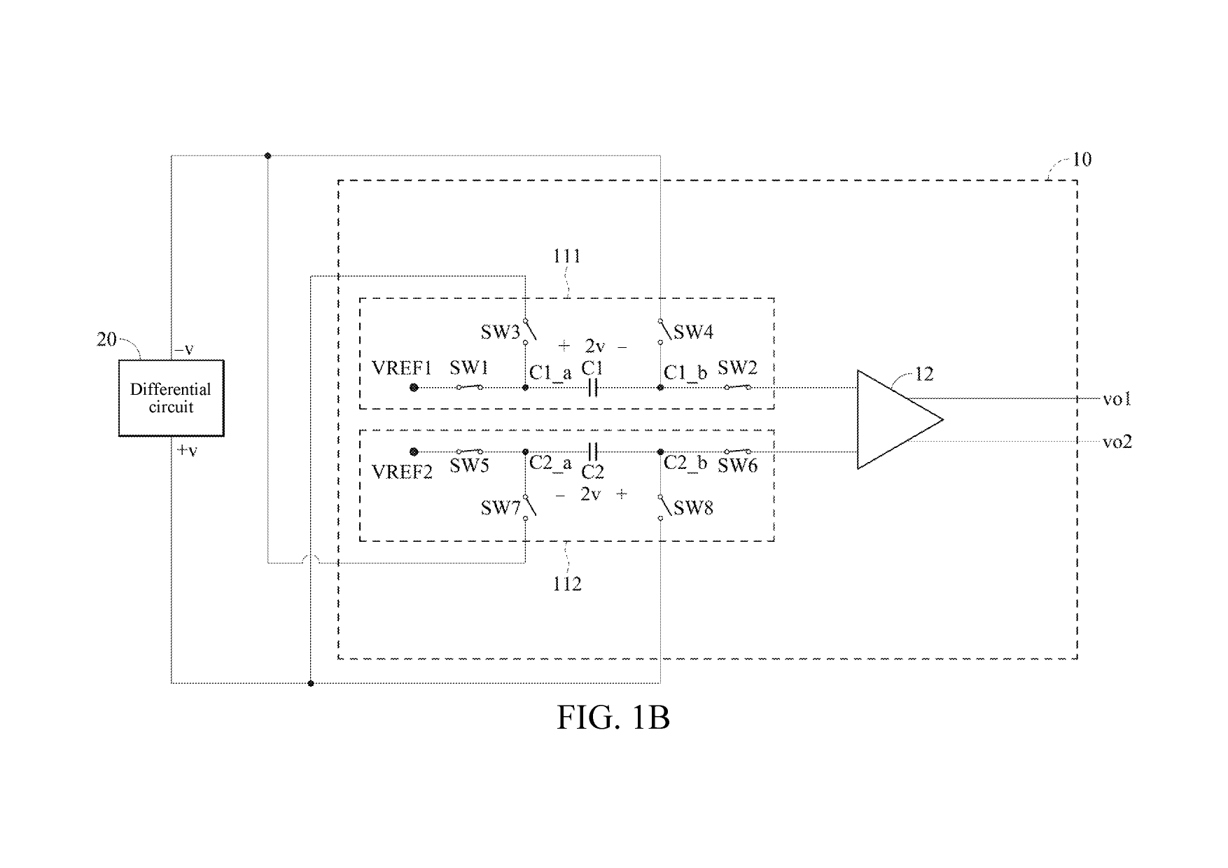

Referring to FIG. 1A, FIG. 1A is a circuit diagram of a differential sampling circuit in a first phase according to a first embodiment. A differential sampling circuit 10 is configured to sample a differential circuit 20. The differential circuit 20 may be a well-known differential amplifier, which has a differential output pair (hereinafter referred to as "a first output" and "a second output"). Embodiments of the present disclosure are explained by taking phase states in which a first output has a signal voltage v with a positive value and a second output has a signal voltage v with a negative value as an example. A person of ordinary skill in the art should understand that the differential circuit 20 may have different output voltages and polarities in different phase states. For example, the first output has a signal voltage v with a negative value, and the second output has a signal voltage v with a positive value. The differential sampling circuit 10 includes an amplifier 12 and one or more switch circuits, and the switch circuits are coupled to an input terminal of the amplifier 12. The coupling allows transmission of a voltage or a current between elements, and is not limited to direct connection or indirect connection through another intermediate element.

As shown in FIG. 1A, the differential sampling circuit 10 of the first embodiment includes an amplifier 12, a first switch circuit 111, and a second switch circuit 112. The first switch circuit 111 is coupled to a first input terminal of the amplifier 12, and the second switch circuit 112 is coupled to a second input terminal of the amplifier 12. The amplifier 12 may be an operational transconductance amplifier (OTA) or a voltage amplifier. The amplifier 12 in this embodiment has a first output terminal vo1 and a second output terminal vo2 to output a pair of differential sampling signals. The amplifier 12 in the embodiments of the present disclosure is illustrated with an example in which the first input terminal is an inverting input terminal, the second input terminal is a non-inverting input terminal, the first output terminal vo1 is a non-inverting output terminal, and the second output terminal vo2 is an inverting output terminal, or vice versa.

The first switch circuit 111 includes a first capacitor C1, first sampling switches SW3 and SW4, and first output switches SW1 and SW2. The sampling switch and the output switch may be, but are not limited to, an insulated gate bipolar transistor (IGBT), a metal oxide semiconductor field effect transistor (MOSFET), a silicon carbide metal oxide semiconductor field effect transistor (SiC MOSFET), a SiC junction transistor, a field effect transistor (FET), a SiC switch, a gallium nitride (GaN) switch, a photoconductive switch, and a bipolar transistor (BJT). In this embodiment, an endpoint C1_a of the first capacitor C1 is coupled to the first sampling switch SW3 and the first output switch SW1, and the first capacitor C1 is coupled to the first output of the differential circuit 20 through the first sampling switch SW3 and is coupled to a first reference terminal VREF1 through the first output switch SW1. The expression "through" may mean that voltage or current transmission between two elements may be performed through an intermediate element. Therefore, the intermediate element may be directly or indirectly connected to the two elements. For example, an intermediate element, such as a resistor (not shown in the figure), may be arranged between the first sampling switch SW3 and the differential circuit 20 or between the first sampling switch SW3 and the first capacitor C1. In addition, an intermediate element may be arranged between the first output switch SW1 and the reference terminal, or between the first output switch SW1 and the first capacitor C1.

The first reference terminal VREF1 provides a reference voltage level of the first switch circuit 111. In some embodiments, the first reference terminal VREF1 is provided with a DC voltage source to provide a stable DC reference potential. Alternatively, the first reference terminal VREF1 and the differential circuit 20 are grounded together. In some other embodiments, an output terminal of a pipeline analog-to-digital converter circuit or a switched-capacitor (SC) circuit is coupled to the first reference terminal VREF1. Based on this, the reference voltage level of the first reference terminal VREF1 may be regulated through a preceding-stage circuit, to adjust the output of the differential sampling circuit 10. In some embodiments, two or more differential sampling circuits 10 may be connected in series. Specifically, the output terminal (the first output terminal vo1 or the second output terminal vo2) of the amplifier 12 of the first differential sampling circuit 10 is coupled to the first reference terminal VREF1 of the second differential sampling circuit 10. In this way, the reference voltage level of the second differential sampling circuit 10 may be regulated through the first differential sampling circuit 10 of the preceding stage.

In this embodiment, an endpoint C1_b of the first capacitor C1 is coupled to the first sampling switch SW4 and the first output switch SW2, and the first capacitor C1 is coupled to the second output of the differential circuit 20 through the first sampling switch SW4 and is coupled to the first input terminal of the amplifier 12 through the first output switch SW2. As described above, an intermediate element may be arranged between the first sampling switch SW4 and the differential circuit 20 or between the first sampling switch SW4 and the first capacitor C1, or an intermediate element may be arranged between the first output switch SW2 and the amplifier 12 or between the first output switch SW2 and the first capacitor C1.

In some embodiments, the sampling switch and the output switch are out of phase with each other. For example, when the first sampling switches SW3 and SW4 are in a short-circuited state (an on state), the first output switches SW1 and SW2 are in an open-circuited state (an off state). On the contrary, when the first sampling switches SW3 and SW4 are in an open-circuited state (an off state), the first output switches SW1 and SW2 are in a short-circuited state (an on state). In some embodiments, the differential sampling circuit 10 includes a controller (not shown in the figure), which is respectively coupled to each sampling switch and each output switch. The controller may generate a first switch signal to control the sampling switch, and generate a second switch signal to control the output switch. The first switch signal and the second switch signal are out of phase with each other. In some other embodiments, the sampling switch and the output switch adopt complementary elements. For example, the sampling switch adopts an N-type field effect transistor, and the output switch adopts a P-type field effect transistor. The controller may control the sampling switch and the output switch based on a same switch signal. In some other embodiments, the controller is coupled to the sampling switch and is coupled to the output switch through an inverter. Alternatively, the controller is coupled to the sampling switch through an inverter and is coupled to the output switch. Therefore, the controller may control the sampling switch and the output switch based on a same switch signal. The controller may be, but is not limited to, a system on a chip (SoC) chip, a central processing unit (CPU), a microcontroller unit (MCU), an application specific integrated circuit (ASIC), a field programmable gate array (FPGA), or a logic circuit.

FIG. 1A shows a state of the differential sampling circuit 10 in the first phase, where the first phase is a signal sampling stage. In this case, the first sampling switches SW3 and SW4 are short-circuited, and the first output switches SW1 and SW2 are open-circuited. Therefore, a positive signal voltage v generated by the first output of the differential circuit 20 and a negative signal voltage v generated by the second output cause the first capacitor C1 to be charged to twice the signal voltage v (in this embodiment, a potential on a left side of the first capacitor C1 is higher than that on a right side). Referring to FIG. 1B, FIG. 1B is a circuit diagram of the differential sampling circuit in a second phase according to the first embodiment. FIG. 1B shows a state of the differential sampling circuit 10 in the second phase, where the second phase is a signal output stage. In this case, the first sampling switches SW3 and SW4 are open-circuited, and the first output switches SW1 and SW2 are short-circuited. Therefore, a potential reference of the first reference terminal VREF1 and the voltage sampled by the first capacitor C1 are superposed and then outputted to the first input terminal of the amplifier 12. The amplifier 12 amplifies a potential difference between the first input terminal and the second input terminal, and generates a differential output signal for output to the first output terminal vo1 and the second output terminal vo2. In some embodiments, the second input terminal of the amplifier 12 is coupled to a reference power supply (not shown in the figure), and the amplifier 12 generates a differential output signal based on a potential difference between an output signal of the first switch circuit 111 and the reference power supply. In this embodiment, the second input terminal of the amplifier 12 is coupled to the second switch circuit 112.

The second switch circuit 112 includes a second capacitor C2, second sampling switches SW7 and SW8, and second output switches SW5 and SW6. The second switch circuit 112 may use the circuit configuration of the first switch circuit 111 in a different embodiment of the present disclosure. Specifically, an endpoint C2_a of the second capacitor C2 is coupled to the second sampling switch SW7 and the second output switch SW5, and the second capacitor C2 is coupled to the second output of the differential circuit 20 through the second sampling switch SW7 and is coupled to a second reference terminal VREF2 through the second output switch SW5. An endpoint C2_b of the second capacitor C2 is coupled to the second sampling switch SW8 and the second output switch SW6, and the second capacitor C2 is coupled to the first output of the differential circuit 20 through the second sampling switch SW8 and is coupled to the second input terminal of the amplifier 12 through the second output switch SW6. In this embodiment, a main configuration difference between the first switch circuit 111 and the second switch circuit 112 is that the two are alternately coupled to the first output and the second output of the differential circuit 20. The second reference terminal VREF2 provides a reference voltage level of the second switch circuit 112. The second reference terminal VREF2 may use the circuit configuration of the first reference terminal VREF1 in a different embodiment of the present disclosure. In some embodiments, the first reference terminal VREF1 is coupled to the second reference terminal VREF2, and the two receive a same reference potential or are grounded together.

As described above, in some embodiments, the sampling switches (the first sampling switches SW3 and SW4 and the second sampling switches SW7 and SW8) and the output switches (the first output switches SW1 and SW2 and the second output switches SW5 and SW6) are out of phase with each other. In addition, the first sampling switches SW3 and SW4 and the second sampling switches SW7 and SW8 may be in phase, and the first output switches SW1 and SW2 and the second output switches SW5 and SW6 may be in phase. For example, referring to FIG. 1A again, in the first phase (the signal sampling phase), the second sampling switches SW7 and SW8 are short-circuited, and the second output switches SW5 and SW6 are open-circuited. Therefore, a positive signal voltage v generated by the first output of the differential circuit 20 and a negative signal voltage v generated by the second output cause the second capacitor C2 to be charged to twice the signal voltage v (in this embodiment, a potential on a right side of the second capacitor C2 is higher than that on a left side). Therefore, in the first phase of this embodiment, potential polarities of the first capacitor C1 and the second capacitor C2 are opposite. Referring to FIG. 1B again, in the second phase (the signal output phase), the second sampling switches SW7 and SW8 are open-circuited, and the second output switches SW5 and SW6 are short-circuited. Therefore, a potential reference of the second reference terminal VREF2 and the voltage sampled by the second capacitor C2 are superposed and then outputted to the second input terminal of the amplifier 12. As shown in FIG. 1A and FIG. 1B, the first capacitor C1 (or the second capacitor C2) of the differential sampling circuit 10 in the first embodiment samples the differential circuit 20 in the first phase, and is charged to twice the signal voltage v of the differential signal. Based on this, the amplifier 12 can achieve signal amplification by at least twice through a single capacitor.

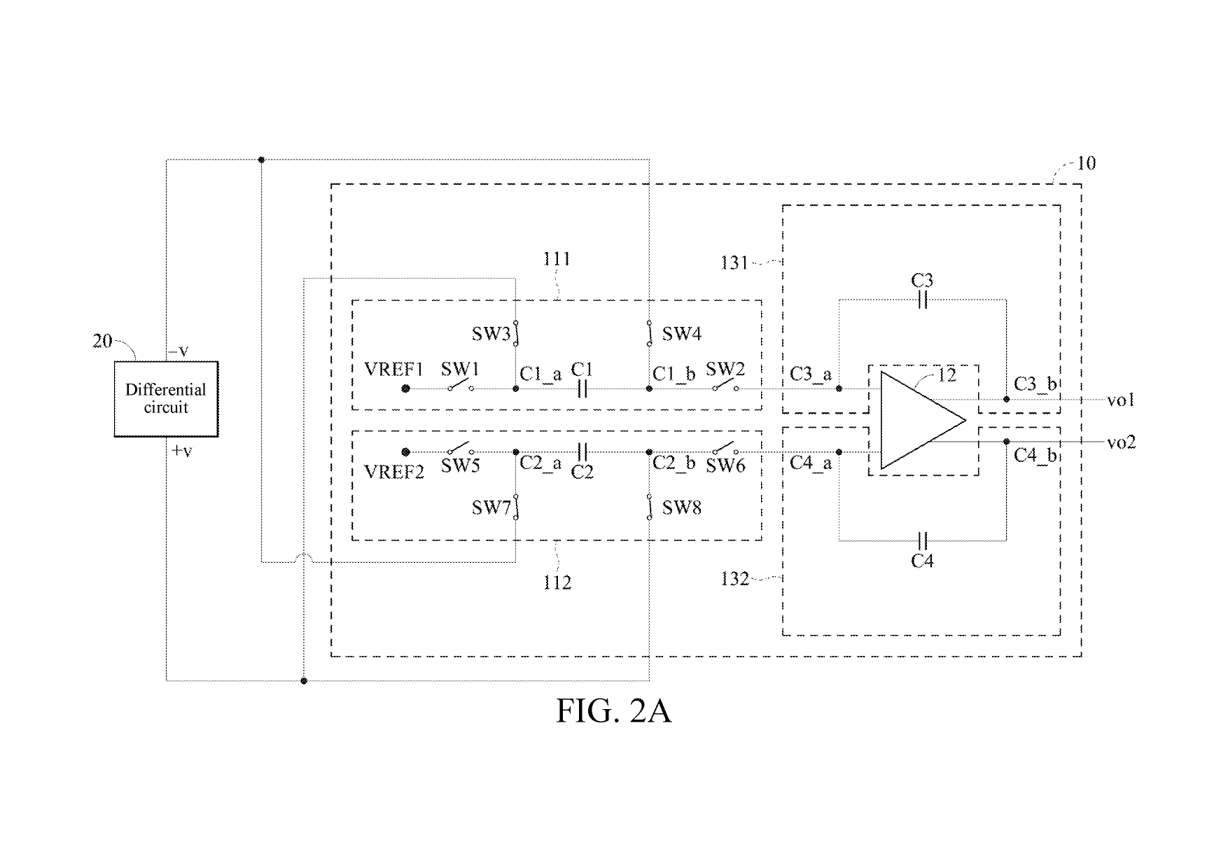

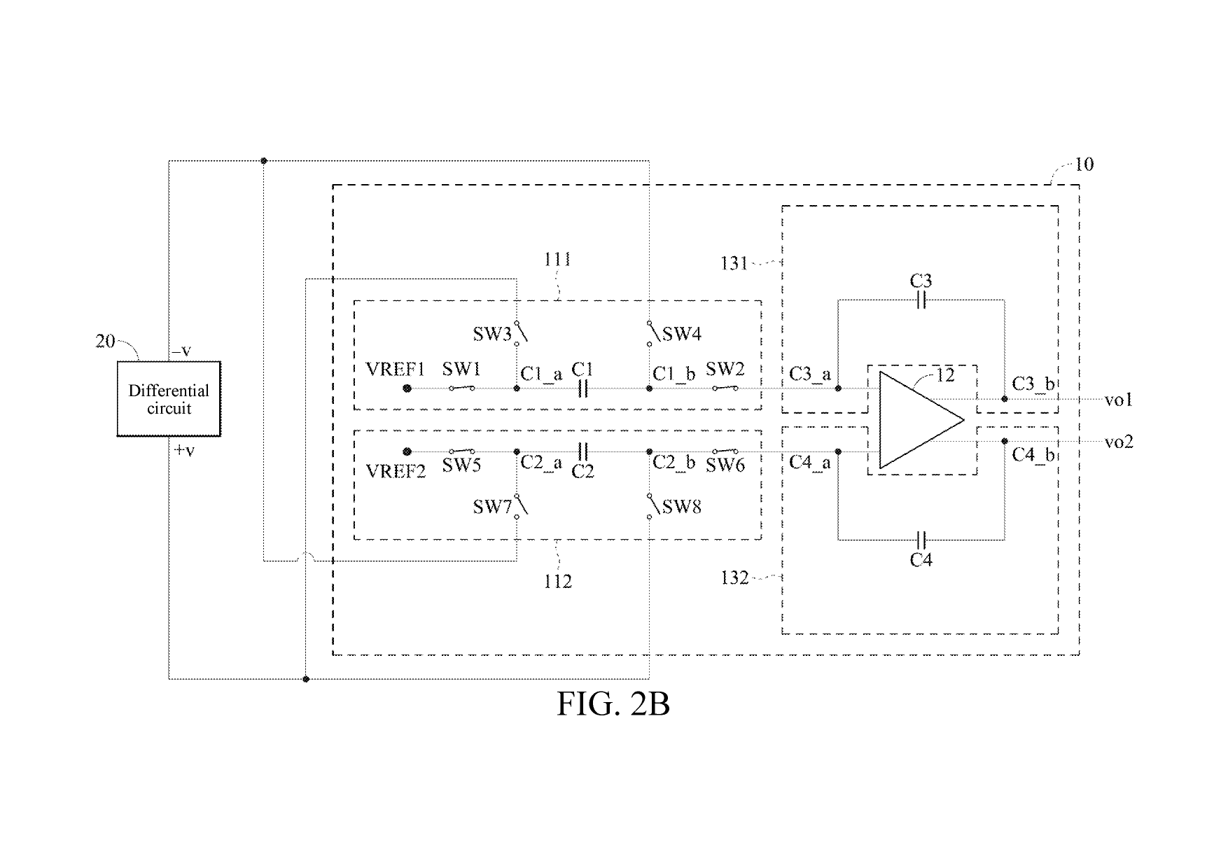

FIG. 2A is a circuit diagram of a differential sampling circuit in a first phase according to a second embodiment. FIG. 2B is a circuit diagram of the differential sampling circuit in a second phase according to the second embodiment. Refer to FIG. 2A and FIG. 2B together. A differential sampling circuit 10 in the second embodiment includes a first switch circuit 111, a second switch circuit 112, an amplifier 12, a first feedback circuit 131, and a second feedback circuit 132. The circuit configurations of the first switch circuit 111, the second switch circuit 112, and the amplifier 12 in the second embodiment may follow at least the first embodiment of the present disclosure. Details are not described herein. In this embodiment, the first feedback circuit 131 includes a third capacitor C3, an endpoint C3_a of the third capacitor C3 is coupled to a first input terminal of the amplifier 12, and an endpoint C3_b of the third capacitor C3 is coupled to a first output terminal vo1 of the amplifier 12. The second feedback circuit 132 includes a fourth capacitor C4, an endpoint C4_a of the fourth capacitor C4 is coupled to a second input terminal of the amplifier 12, and an endpoint C4_b of the fourth capacitor C4 is coupled to a second output terminal vo2 of the amplifier 12. The first feedback circuit 131 (or the second feedback circuit 132) and the amplifier 12 are configured as an integrator circuit, and an output signal generated after the first switch circuit 111 (or the second switch circuit 112) samples a signal voltage v may be magnified and then stored in integrating capacitors (that is, the third capacitor C3 and the fourth capacitor C4 in this embodiment), to achieve low-pass filtering or another application of the output signal. In some other embodiments, the differential sampling circuit 10 is provided with only one of the first feedback circuit 131 and the second feedback circuit 132. Therefore, the differential sampling circuit 10 may process the output signal of the output terminal of only one of the two through the integrator circuit.

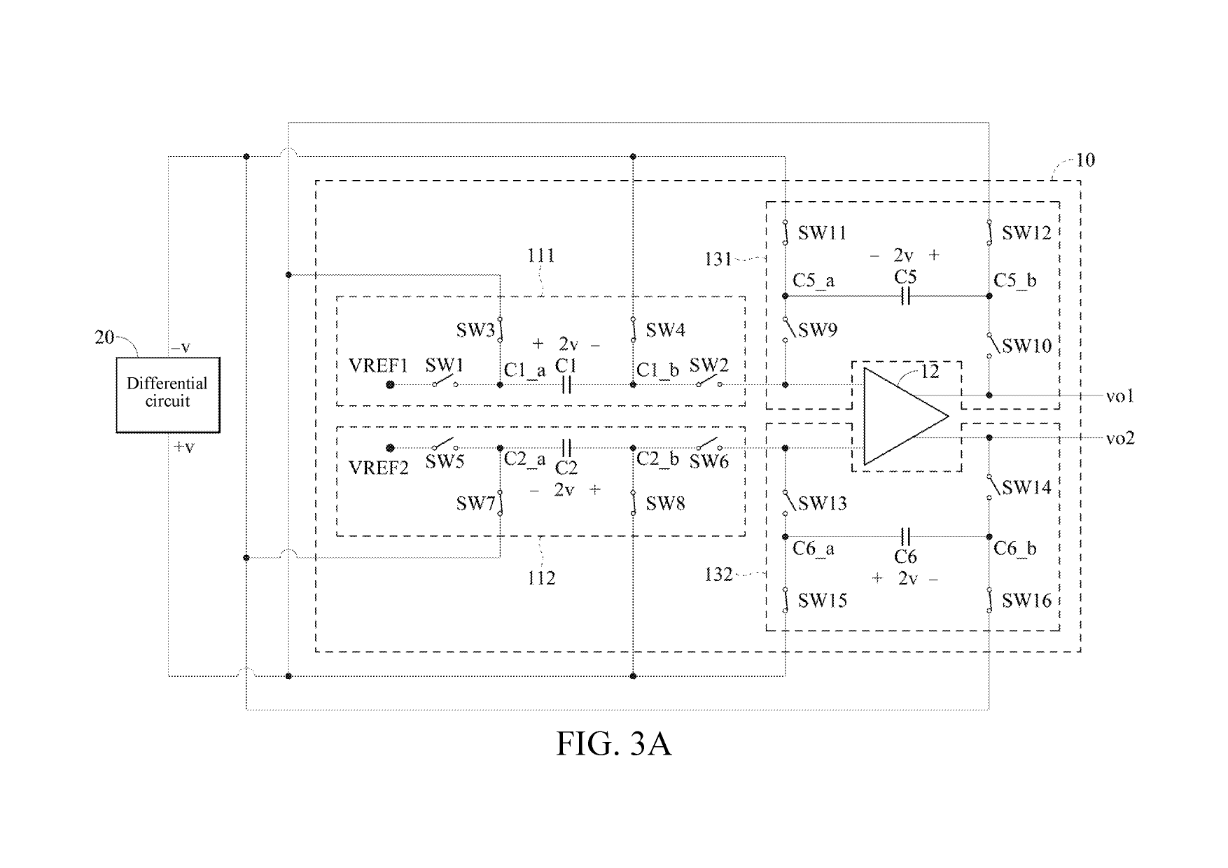

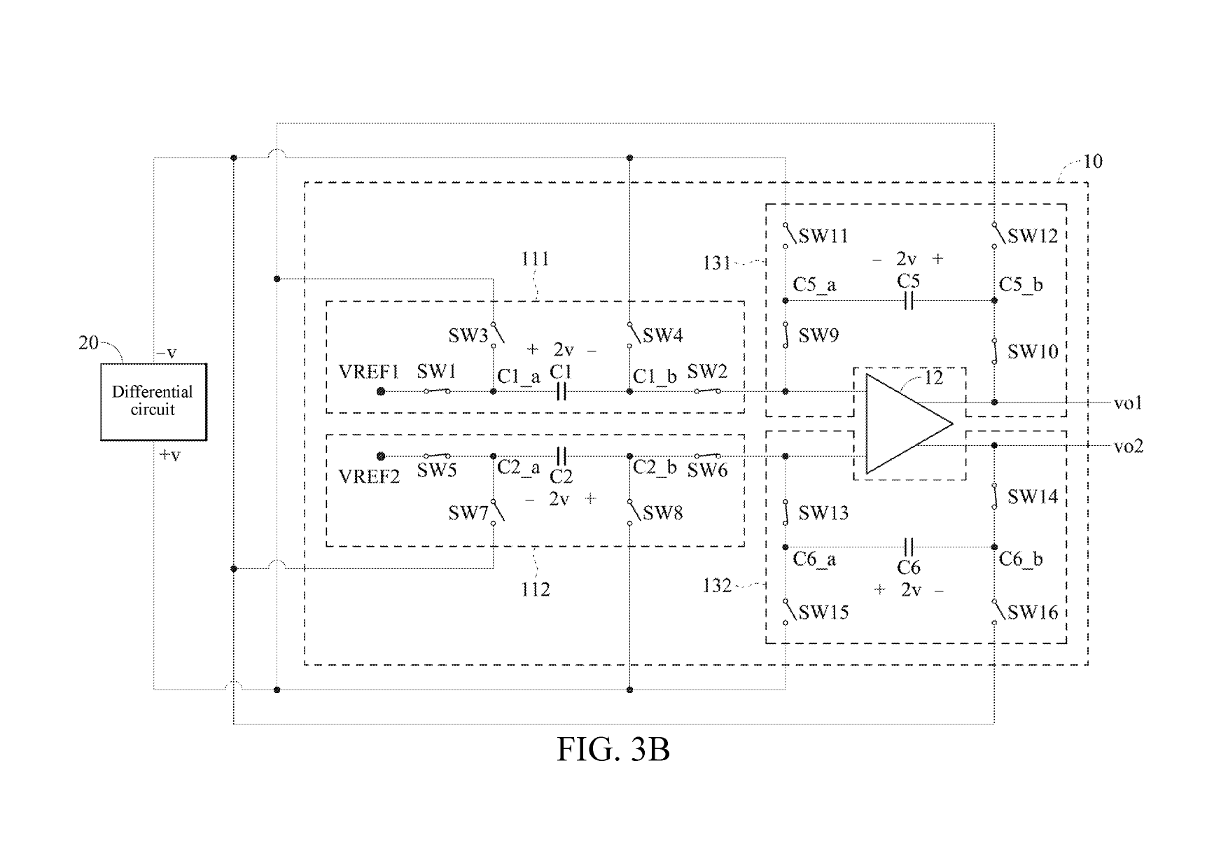

FIG. 3A is a circuit diagram of a differential sampling circuit in a first phase according to a third embodiment. FIG. 3B is a circuit diagram of the differential sampling circuit in a second phase according to the third embodiment. Refer to FIG. 3A and FIG. 3B together. A differential sampling circuit 10 in the third embodiment includes a first switch circuit 111, a second switch circuit 112, an amplifier 12, a first feedback circuit 131, and a second feedback circuit 132. The circuit configurations of the first switch circuit 111, the second switch circuit 112, and the amplifier 12 in the third embodiment may follow at least the first embodiment of the present disclosure. Details are not described herein. In this embodiment, the first feedback circuit 131 includes a third capacitor C5, third sampling switches SW11 and SW12, and third output switches SW9 and SW10. An endpoint C5_a of the third capacitor C5 is coupled to the third sampling switch SW11 and the third output switch SW9, and the third capacitor C5 is coupled to the second output of the differential circuit 20 through the third sampling switch SW11 and is coupled to a first input terminal of the amplifier 12 through the third output switch SW9. An endpoint C5_b of the third capacitor C5 is coupled to the third sampling switch SW12 and the third output switch SW10, and the third capacitor C5 is coupled to the first output of the differential circuit 20 through the third sampling switch SW12 and is coupled to a first output terminal vo1 of the amplifier 12 through the third output switch SW10. The second feedback circuit 132 includes a fourth capacitor C6, fourth sampling switches SW15 and SW16, and fourth output switches SW13 and SW14. An endpoint C6_a of the fourth capacitor C6 is coupled to the fourth sampling switch SW15 and the fourth output switch SW13, and the fourth capacitor C6 is coupled to the first output of the differential circuit 20 through the fourth sampling switch SW15 and is coupled to a second input terminal of the amplifier 12 through the fourth output switch SW13. An endpoint C6_b of the fourth capacitor C6 is coupled to the fourth sampling switch SW16 and the fourth output switch SW14, and the fourth capacitor C6 is coupled to the second output of the differential circuit 20 through the fourth sampling switch SW16 and is coupled to a second output terminal vo2 of the amplifier 12 through the fourth output switch SW14.

As described above, in some embodiments, the sampling switches (the third sampling switches SW11 and SW12 and the fourth sampling switches SW15 and SW16) and the output switches (the third output switches SW9 and SW10 and the fourth output switches SW13 and SW14) are out of phase with each other. In addition, the first sampling switches SW3 and SW4 and the third sampling switches SW11 and SW12 may be in phase, and the first output switches SW1 and SW2 and the third output switches SW9 and SW10 may be in phase. For example, referring to FIG. 3A, in the first phase (a signal sampling stage), the first sampling switches SW3 and SW4, the second sampling switches SW7 and SW8, the third sampling switches SW11 and SW12, and the fourth sampling switches SW15 and SW16 are short-circuited, and the first output switches SW1 and SW2, the second output switches SW5 and SW6, the third output switches SW9 and SW10, and the fourth output switches SW13 and SW14 are open-circuited. Therefore, a positive signal voltage v generated by the first output of the differential circuit 20 and a negative signal voltage v generated by the second output cause the first capacitor C1 to be charged to twice the signal voltage v (in this embodiment, a potential on a left side of the first capacitor C1 is higher than that on a right side), cause the third capacitor C5 to be charged to twice the signal voltage v (in this embodiment, a potential on a right side of the third capacitor C5 is higher than that on a left side), cause the second capacitor C2 to be charged to twice the signal voltage v (in this embodiment, a potential on a right side of the second capacitor C2 is higher than that on a left side), and cause the fourth capacitor C6 to be charged to twice the signal voltage v (in this embodiment, a potential on a left side of the fourth capacitor C6 is higher than that on a right side). Therefore, in the first phase of this embodiment, potential polarities of the first capacitor C1 and the third capacitor C5 are opposite, and potential polarities of the second capacitor C2 and the fourth capacitor C6 are opposite. Referring to FIG. 3B, in the second phase (a signal output stage), the first sampling switches SW3 and SW4, the second sampling switches SW7 and SW8, the third sampling switches SW11 and SW12, and the fourth sampling switches SW15 and SW16 are open-circuited, and the first output switches SW1 and SW2, the second output switches SW5 and SW6, the third output switches SW9 and SW10, and the fourth output switches SW13 and SW14 are short-circuited.

As shown in FIG. 3A and FIG. 3B, the first capacitor C1 of the first switch circuit 111 (or the second capacitor C2 of the second switch circuit 112) in the third embodiment samples the differential circuit 20 in the first phase, and is charged to twice the signal voltage v of the differential signal. In addition, the third capacitor C5 of the first feedback circuit 131 (or the fourth capacitor C6 of the second feedback circuit 132) samples the differential circuit 20, and is charged to twice the signal voltage v of the differential signal. Because the potential polarities of the first capacitor C1 and the third capacitor C5 are opposite, the first capacitor C1 attracts positive charges from the third capacitor C5 in the second phase. Based on the charge conservation, the potential stored in the third capacitor C5 becomes four times the signal voltage v. Similarly, because the potential polarities of the second capacitor C2 and the fourth capacitor C6 are opposite, the second capacitor C2 attracts negative charges from the fourth capacitor C6 in the second phase, causing the potential stored in the fourth capacitor C6 to become four times the signal voltage v. Based on this, the amplifier 12 can achieve signal amplification by at least four times through a pair of capacitors.

A conventional SC circuit uses three first capacitors C1 and a capacitor of a differential signal amplifier 12 to achieve amplification by four times, and therefore a feedback factor is 1/4. Correspondingly, the differential sampling circuit 10 in the third embodiment achieves amplification by four times through the first capacitor C1 and the third capacitor C5 (or the second capacitor C2 and the fourth capacitor C6), and therefore a feedback factor is 1/2. Therefore, in this embodiment, due to the high feedback factor of the differential sampling circuit 10, power consumption and a gain demand of the amplifier 12 are reduced. In some other embodiments, the differential sampling circuit 10 is provided with only one of the first feedback circuit 131 and the second feedback circuit 132. Therefore, the differential sampling circuit 10 may adjust an amplification factor of the output signal of the output terminal of only one of the two.

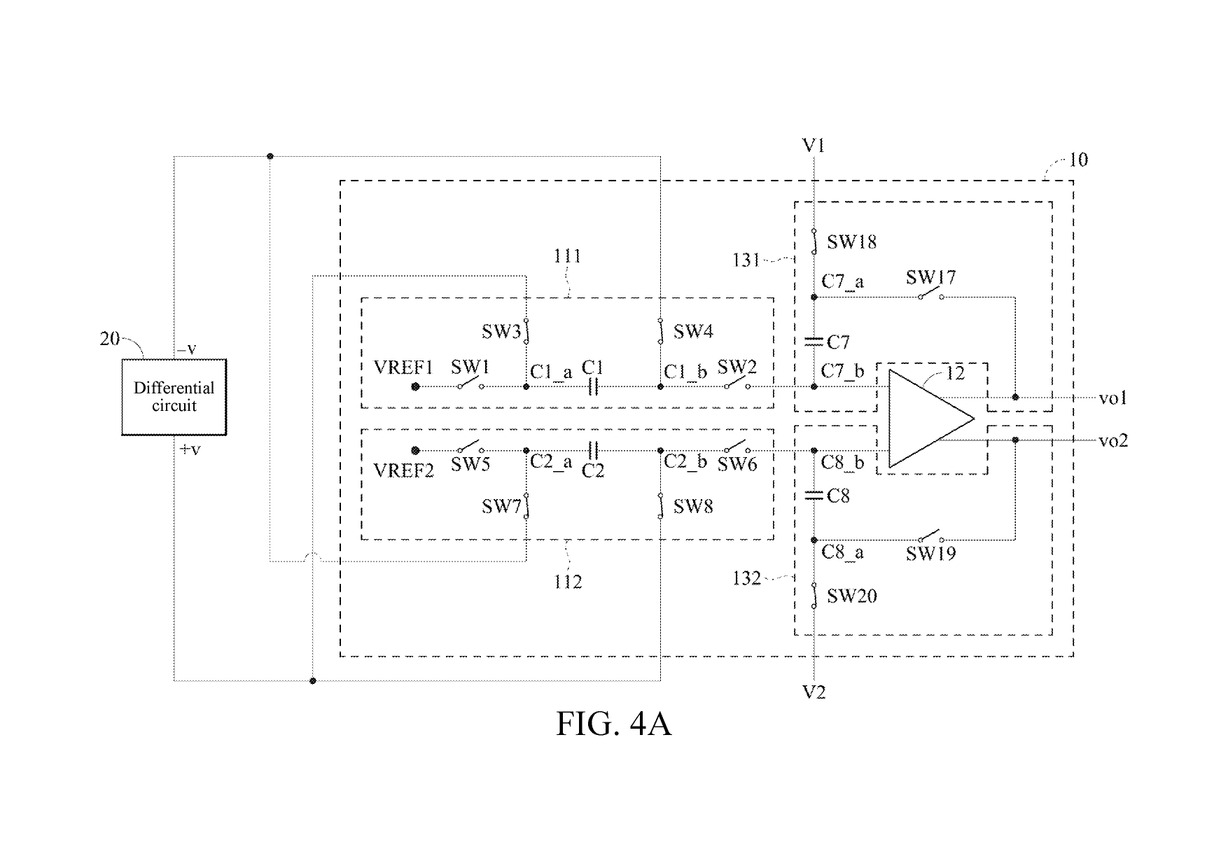

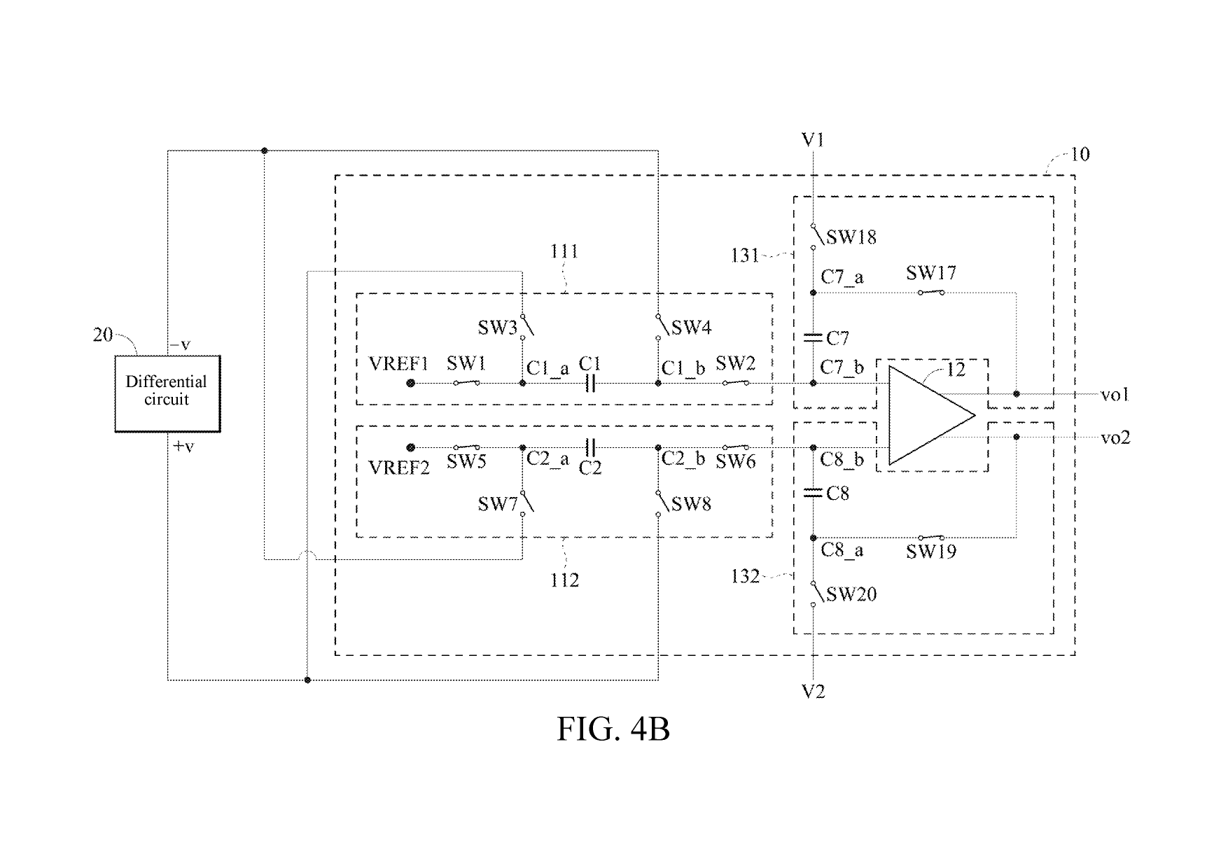

FIG. 4A is a circuit diagram of a differential sampling circuit in a first phase according to a fourth embodiment. FIG. 4B is a circuit diagram of the differential sampling circuit in a second phase according to the fourth embodiment. Refer to FIG. 4A and FIG. 4B together. A differential sampling circuit 10 in the fourth embodiment includes a first switch circuit 111, a second switch circuit 112, an amplifier 12, a first feedback circuit 131, and a second feedback circuit 132. The circuit configurations of the first switch circuit 111, the second switch circuit 112, and the amplifier 12 in the fourth embodiment may follow at least the first embodiment of the present disclosure. Details are not described herein. In this embodiment, the first feedback circuit 131 includes a third capacitor C7, a third sampling switch SW18, a third output switch SW17, and a first voltage source V1. An endpoint C7_a of the third capacitor C7 is coupled to the third sampling switch SW18 and the third output switch SW17, and the third capacitor C7 is coupled to the first voltage source V1 through the third sampling switch SW18 and is coupled to a first output terminal vo1 of the amplifier 12 through the third output switch SW17. An endpoint C7_b of the third capacitor C7 is coupled to the first input terminal of the amplifier 12. The second feedback circuit 132 includes a fourth capacitor C8, a fourth sampling switch SW20, a fourth output switch SW19, and a second voltage source V2. An endpoint C8_a of the fourth capacitor C8 is coupled to the fourth sampling switch SW20 and the fourth output switch SW19, and the fourth capacitor C8 is coupled to the second voltage source V2 through the fourth sampling switch SW20 and is coupled to a second output terminal vo2 of the amplifier 12 through the fourth output switch SW19. An endpoint C8_b of the fourth capacitor C8 is coupled to a second input terminal of the amplifier 12.

The first voltage source V1 (the second voltage source V2) may be used as a DC voltage source to provide a DC bias voltage, or may be used as a signal source to generate a direct current or alternating current signal. For example, the first voltage source V1 (the second voltage source V2) is used as a stable DC voltage source, and may reset the third capacitor C7 (the fourth capacitor C8) in the first phase every time. For another example, the first voltage source V1 (the second voltage source V2) may receive an output signal from an external analog-to-digital converter circuit. Therefore, the amplifier 12 may respectively receive an output signal of the first switch circuit 111 (the second switch circuit 112) and the output signal of the digital converter in different phases, and then amplify them to generate output signals. In some embodiments, in response to the inverting signals outputted by the first switch circuit 111 and the second switch circuit 112, polarities of the first voltage source V1 and the second voltage source V2 are opposite. For example, the first voltage source V1 provides a DC bias voltage of +3.3 V, and the second voltage source V2 provides a DC bias voltage of −3.3 V. For another example, the first voltage source V1 provides a first alternating current signal, and the second voltage source V2 provides a second alternating current signal. A phase difference between the first alternating current signal and the second alternating current signal is 180 degrees. In some embodiments, the output terminal (the first output terminal vo1 or the second output terminal vo2) of the amplifier 12 of the first differential sampling circuit 10 is used as the first voltage source V1 (or the second voltage source V2) of the second differential sampling circuit 10. In this way, the amplifier 12 of the second differential sampling circuit 10 may be regulated through the first differential sampling circuit 10 of the preceding stage.

As described above, in some embodiments, the sampling switches (the third sampling switch SW18 and the fourth sampling switch SW20) and the output switches (the third output switch SW17 and the fourth output switch SW19) are out of phase with each other. In addition, the first sampling switches SW3 and SW4 and the third sampling switch SW18 may be in phase, and the first output switches SW1 and SW2 and the third output switch SW17 may be in phase. For example, referring to FIG. 4A, in the first phase (a signal sampling stage), the first sampling switches SW3 and SW4, the second sampling switches SW7 and SW8, the third sampling switch SW18, and the fourth sampling switch SW20 are short-circuited, and the first output switches SW1 and SW2, the second output switches SW5 and SW6, the third output switch SW17, and the fourth output switch SW19 are open-circuited. Therefore, a positive signal voltage v generated by the first output of the differential circuit 20 and a negative signal voltage v generated by the second output cause the first capacitor C1 and the second capacitor C2 to be charged to twice the signal voltage v. In addition, the first voltage source V1 charges the third capacitor C7, and the second voltage source V2 charges the fourth capacitor C8. Referring to FIG. 4B, in the second phase (a signal output stage), the first sampling switches SW3 and SW4, the second sampling switches SW7 and SW8, the third sampling switch SW18, and the fourth sampling switch SW20 are open-circuited, and the first output switches SW1 and SW2, the second output switches SW5 and SW6, the third output switch SW17, and the fourth output switch SW19 are short-circuited.

As shown in FIG. 4A and FIG. 4B, the first capacitor C1 of the first switch circuit 111 (or the second capacitor C2 of the second switch circuit 112) in the fourth embodiment samples the differential circuit 20 in the first phase, and is charged to twice the signal voltage v of the differential signal. In addition, the third capacitor C7 of the first feedback circuit 131 (or the fourth capacitor C8 of the second feedback circuit 132) receives an external DC bias voltage (or a signal), and is charged to a DC bias voltage (or signal) potential. Because of the potential difference between the first capacitor C1 and the third capacitor C7, the first capacitor C1 attracts charges from the third capacitor C7 in the second phase, which changes the potential stored in the third capacitor C7 and thereby affects the output signal. Similarly, because of the potential difference between the second capacitor C2 and the fourth capacitor C8, the second capacitor C2 attracts charges from the fourth capacitor C8 in the second phase, which changes the potential stored in the fourth capacitor C8 and thereby affects the output signal. Based on this, the differential sampling circuit 10 in this embodiment may adjust the output signal through the first voltage source V1 and the second voltage source V2.

Although the disclosure has been described in considerable detail with reference to certain preferred embodiments thereof, the disclosure is not for limiting the scope of the invention. Persons having ordinary skill in the art may make various modifications and changes without departing from the scope and spirit of the disclosure. Therefore, the scope of the appended claims should not be limited to the description of the preferred embodiments described above.

What is claimed is:

1. A differential sampling circuit, configured to sample a differential circuit, wherein the differential circuit comprises a first output and a second output, and the differential sampling circuit comprises:
an amplifier; and
a first switch circuit, comprising a first capacitor, a pair of first sampling switches, and a pair of first output switches, wherein one end of the first capacitor is coupled to the first output of the differential circuit through one of the pair of first sampling switches and is coupled to a first reference terminal through the one of the pair of first output switches, and the other end of the first capacitor is coupled to the second output of the differential circuit through the other of the pair of first sampling switches and is coupled to a first input terminal of the amplifier through the other of the pair of first output switches.

2. The differential sampling circuit according to claim 1, wherein the first reference terminal is coupled to an output terminal of an analog-to-digital converter circuit.

3. The differential sampling circuit according to claim 1, wherein the first reference terminal is coupled to an output terminal of a switched-capacitor (SC) circuit.

4. The differential sampling circuit according to claim 1, wherein the first reference terminal is coupled to an output terminal of an amplifier of another differential sampling circuit.

5. The differential sampling circuit according to claim 1, wherein the amplifier is an operational transconductance amplifier.

6. The differential sampling circuit according to claim 1, further comprising a second switch circuit, wherein the second switch circuit comprises a second capacitor, a pair of second sampling switches, and a pair of second output switches, one end of the second capacitor is coupled to the second output of the differential circuit through one of the pair of second sampling switches and is coupled to a second reference terminal through the one of the pair of second output switches, and the other end of the second capacitor is coupled to the first output of the differential circuit through the other of the pair of second sampling switches and is coupled to a second input terminal of the amplifier through the other of the pair of second output switches.

7. The differential sampling circuit according to claim 6, wherein the first reference terminal is coupled to the second reference terminal.

8. The differential sampling circuit according to claim 6, wherein the pair of first sampling switches and the pair of first output switches are out of phase with each other, and the pair of second sampling switches and the pair of second output switches are out of phase with each other.

9. The differential sampling circuit according to claim 1, further comprising a first feedback circuit, wherein the first feedback circuit comprises a third capacitor, one end of the third capacitor is coupled to the first input terminal of the amplifier, and the other end of the third capacitor is coupled to a first output terminal of the amplifier.

10. The differential sampling circuit according to claim 9, further comprising a second feedback circuit, wherein the second feedback circuit comprises a fourth capacitor, one end of the fourth capacitor is coupled to a second input terminal of the amplifier, and the other end of the fourth capacitor is coupled to a second output terminal of the amplifier.

11. The differential sampling circuit according to claim 1, further comprising a first feedback circuit, wherein the first feedback circuit comprises a third capacitor, a pair of third sampling switches, and a pair of third output switches, one end of the third capacitor is coupled to the second output of the differential circuit through one of the pair of third sampling switches and is coupled to the first input terminal of the amplifier through the one of the pair of third output switches, and the other end of the third capacitor is coupled to the first output of the differential circuit through the other of the pair of third sampling switches and is coupled to a first output terminal of the amplifier through the other of the pair of third output switches.

12. The differential sampling circuit according to claim 11, wherein the pair of first sampling switches and the pair of third sampling switches are in phase, and the pair of third sampling switches and the pair of third output switches are out of phase with each other.

13. The differential sampling circuit according to claim 11, further comprising a second feedback circuit, wherein the second feedback circuit comprises a fourth capacitor, a pair of fourth sampling switches, and a pair of fourth output switches, one end of the fourth capacitor is coupled to the first output of the differential circuit through one of the pair of fourth sampling switches and is coupled to a second input terminal of the amplifier through the one of the pair of fourth output switches, and the other end of the fourth capacitor is coupled to the second output of the differential circuit through the other of the pair of fourth sampling switches and is coupled to a second output terminal of the amplifier through the other of the pair of fourth output switches.

14. The differential sampling circuit according to claim 1, further comprising a first feedback circuit, wherein the first feedback circuit comprises a third capacitor, a third sampling switch, and a third output switch, one end of the third capacitor is coupled to a first voltage source through the third sampling switch and is coupled to a first output terminal of the amplifier through the third output switch, and the other end of the third capacitor is coupled to the first input terminal of the amplifier.

15. The differential sampling circuit according to claim 14, wherein the pair of first sampling switches and the third sampling switch are in phase, and the third sampling switch and the third output switch are out of phase with each other.

16. The differential sampling circuit according to claim 14, wherein the first voltage source is a DC voltage source.

17. The differential sampling circuit according to claim 14, wherein the first voltage source is an output terminal of an analog-to-digital converter circuit.

18. The differential sampling circuit according to claim 14, wherein the first voltage source is an output terminal of an amplifier of another differential sampling circuit.

19. The differential sampling circuit according to claim 14, further comprising a second feedback circuit, wherein the second feedback circuit comprises a fourth capacitor, a fourth sampling switch, and a fourth output switch, one end of the fourth capacitor is coupled to a second voltage source though the fourth sampling switch and is coupled to a second output terminal of the amplifier through the fourth output switch, and the other end of the fourth capacitor is coupled to a second input terminal of the amplifier.

20. The differential sampling circuit according to claim 19, wherein polarities of the first voltage source and the second voltage source are opposite.
